(19) United States
(12) Patent Application Publication
(10) Pub. No.: US 2010/0019322 A1
(43) Pub. Date: Jan. 28, 2010

(54) SEMICONDUCTOR DEVICE AND METHOD OF MANUFACTURING

(75) Inventors: Xiangdong Chen, Poughquag, NY (US); Haining S. Yang, Wappingers Falls, NY (US)

Correspondence Address: GREENBLUM & BERNSTEIN, P.L.C., 1950 ROLAND CLARKE PLACE, RESTON, VA, 20191, US

(73) Assignee: International Business Machines Corporation, Armonk, NY (US)

(21) Appl. No.: 12/178,326

(22) Filed: Jul. 23, 2008

(51) Int. Cl. H01L 29/72; H01L 21/76; G06F 17/50

(52) U.S. Cl. 257/368; 438/425; 716/1; 257/E29.127

(57) ABSTRACT

A semiconductor device and method is provided that has a stress component for increased device performance. The method integrates a stress material into a trench used typically for an isolation structure. The method includes forming an isolation trench through a SOI layer and an underlying BOX layer. The method further includes filling the isolation trench with stress material having characteristics different than the BOX layer.

### FIELD OF THE INVENTION

The present invention relates to a semiconductor device and a method of manufacturing and, more particularly, to a semiconductor device having a stress component for increased device performance and a method of manufacturing the semiconductor device.

### BACKGROUND

CMOS technology embodied as a high performance, low-power chip, has been widely used in electronic devices because of its scaleable. However, continuing this CMOS performance trend has become extremely difficult because the industry is approaching the fundamental physical limits of CMOS scaling. For this reason, the semiconductor industry has been aggressively seeking new ways to make electric charges move faster through device channels so as to increase circuit speeds and reduce power consumption.

Generally, CMOS technology includes metal-oxide semiconductor transistors having a substrate made of a semiconductor material, such as silicon. The transistors typically include a source region, a channel region and a drain region within the substrate. The channel region is located between the source and the drain regions. A gate stack, which usually includes a conductive material, a gate oxide layer and sidewall spacers, is generally provided above the channel region. More particularly, the gate oxide layer is typically provided on the substrate over the channel region, while the gate conductor is usually provided above the gate oxide layer. The sidewall spacers help protect the sidewalls of the gate conductor. Shallow trench isolation structures (STI) typically are used to isolate the gates (transistors).

To improve the current flowing through the channel, the mobility of the carriers in the channel can be increased. This typically increases the operation speed of the transistor. It is further known that mechanical stresses within a semiconductor device substrate can modulate device performance by, for example, increasing the mobility of the carriers in the semiconductor device. That is, stresses within a semiconductor device are known to enhance semiconductor device characteristics. Thus, to improve the characteristics of a semiconductor device, tensile and/or compressive stresses are created in the channel of the n-type devices (e.g., NFETs) and/or p-type devices (e.g., PFETs).

However, the same stress component, for example tensile stress or compressive stress, improves the device characteristics of one type of device (i.e., n-type device or p-type device) while discriminatively affecting the characteristics of the other type device. As such, the stress components should be engineered and applied differently for NFETs and PFETs. That is, because the type of stress which is beneficial for the performance of an NFET is generally disadvantageous for the performance of the PFET. More particularly, when a device is in tension (in the direction of current flow in a planar device), the performance characteristics of the NFET are enhanced while the performance characteristics of the PFET are diminished.

In known processes for implementing stresses in FETs, distinct processes and/or materials are used to create such stresses. For example, Ge has been used as a channel material to enhance electron and hole mobility for both NFET and PFET devices. However, current processes pose integration problems. As an illustrative example, it has been found that SiGe material does not grow uniformly, which can lead to serious processing problems such as, for example, junction leakage problems.

Accordingly, there exists a need in the art to overcome the deficiencies and limitations described hereinabove.

### SUMMARY

In a first aspect of the invention, a method comprises forming an isolation trench through a SOI layer and an underlying BOX layer. The method further comprises filling the isolation trench with stress material having characteristics different than the BOX layer.

In another aspect of the invention, a structure comprises a trench isolation structure formed in a BOX layer and extending toward an underlying substrate and underneath an overlying SOI layer. The trench isolation structure is filled with an oxide based material that has characteristics different from the BOX layer and which provides a stress component to an adjacent gate structure.

In a further aspect of the invention, a design structure is embodied in a machine readable medium for designing, manufacturing, or testing an integrated circuit. The design structure comprises a trench isolation structure formed in a BOX layer and extending toward an underlying substrate and underneath an overlying SOI layer. The trench isolation structure is filled with an oxide based material that has characteristics different from the BOX layer and which provides a stress component to an adjacent gate structure.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIGS. 1-8 show intermediate structures and respective processing steps in accordance with aspects of the invention;

FIG. 9 shows a final structure and respective processing steps according to the aspects of the invention;

FIG. 10 is a graph showing improvements which are attainable in implementing the present invention; and

FIG. 11 is a flow diagram of a design process used in semiconductor design, manufacture, and/or test.

### DETAILED DESCRIPTION

The present invention relates to semiconductor devices, a design structure and a method of manufacturing semiconductor devices and, more particularly, to a semiconductor device having a stress component for increased device performance and a method of manufacturing the semiconductor device. In implementation, the present invention provides a process to integrate a stress material into a trench used typically for an isolation structure. Advantageously, the trench is provided in an underlying BOX or oxide layer which increases the volume of the stress material and hence the stress concentration. The devices manufactured using the processes of the present invention will benefit from strained Si mobility enhancement.

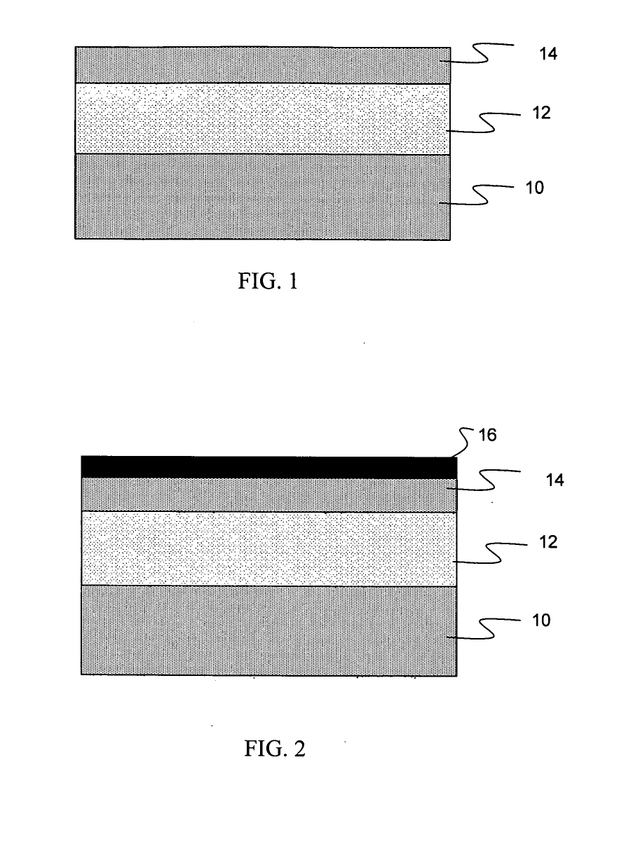

FIGS. 1-8 show intermediate structures and respective processing steps in accordance with the invention. In particular, FIG. 1 shows a starting structure in accordance with the invention. In this starting structure, a BOX (buried oxide layer 12 is formed over an underlying substrate 10 using conventional bonding and or deposition processes known to those of skill in the art. In embodiments, the BOX 12 may be about 150 nm in thickness; although this thickness should not be considered a limiting factor as other dimensions are also contemplated by the present invention. An SOI layer 14 is deposited on the BOX 12. In embodiments, the SOI layer 14 may be partially or fully depleted, depending on the implementation of the device. The SOI layer 14 may range in thickness from about 10 nm to 100 nm. As a more specific example, when the SOI layer 14 is fully depleted it may have a thickness of about 10-30 nm; whereas, when the SOI layer 14 is partially depleted it may have a thickness of about 50 nm to 80 nm.

In FIG. 2, a pad nitride layer 16 is deposited on the structure of FIG. 1. The pad nitride layer 16 may be deposited in any conventional manner such as, for example, using a conventional chemical deposition process.

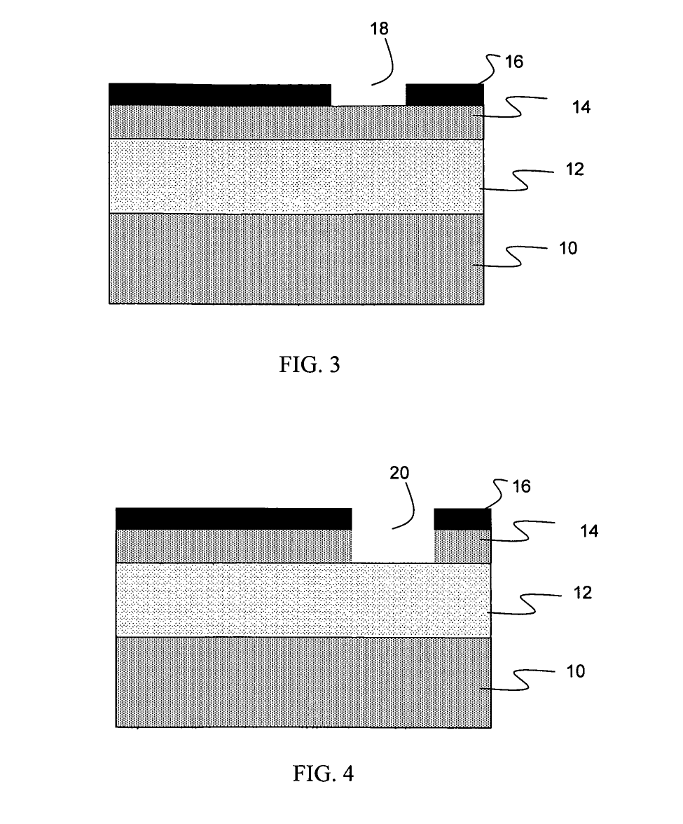

In FIG. 3, an opening 18 is formed in the pad nitride layer 16 using a conventional lithography and etching process. By way of example, the lithography step entails applying a photoresist, exposing the photoresist to a pattern of radiation, and developing the pattern utilizing a conventional resist developer. More specifically, a photoresist (not shown) is placed over the pad nitride layer 16 and exposed to radiation (e.g., light). Once developed, a conventional reactive ion etch (RIE) can be performed to form the opening 18.

In FIG. 4, an opening 20 is formed in the SOI layer 14, using the pad nitride layer 16 as a hard mask. The opening 20 may be formed using a RIE, for example.

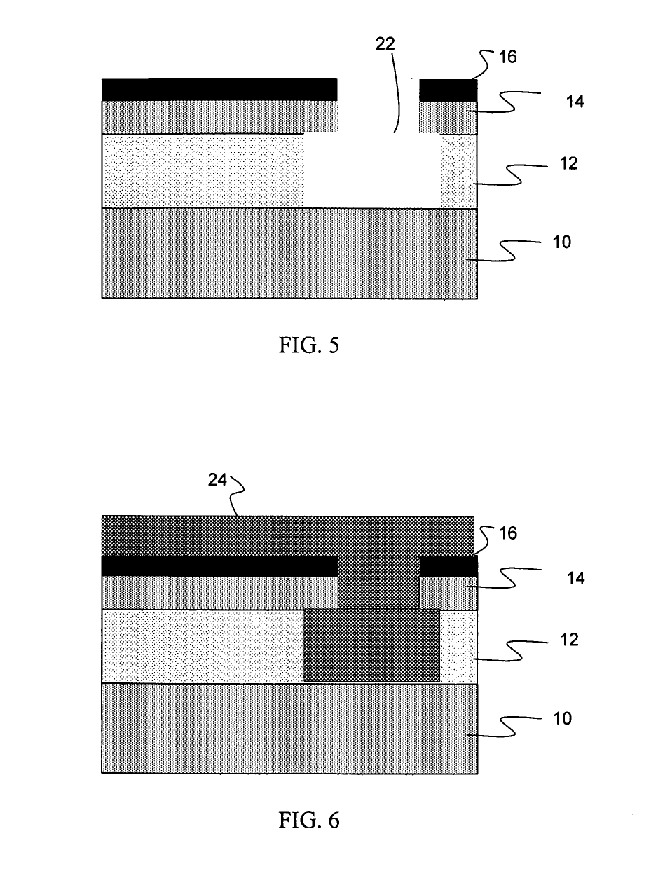

As shown in FIG. 5, the BOX 14 is opened to form a trench 22. In embodiments, the trench 22 can be formed using a RIE or wet chemical etch such as, for example, dilute HF. The etching is an isotropic etch such that a lateral etch can be provided under the SOI layer 14. In embodiments, the trench 22 can be formed entirely through the BOX 12 to the underlying substrate 10. This would provide the maximum volume for a subsequent stress material to be deposited therein. In further embodiments, the trench 22 can be provided partially through the BOX 12.

In embodiments, portions of the BOX 12 remain connected between the substrate 10 and the SOI layer 14 in order to provide the requisite structure needed between the substrate 10 and the SOI layer 14. In embodiments, it is contemplated that about 50 nm of BOX 12 remain after the etching process; although, this is only one of many different examples contemplated by the invention. For example, in a symmetrical gate structure, some BOX 12 remains under the channel (with the trench extending toward the channel of the gate structure); however, in asymmetrical gate structures the BOX 12 may remain at other locations. In one specific non-limiting illustrative example, in an “I” shaped gate structure, portions of the BOX 12 may remain at the horizontal portions of the gate structure and be etched completed away in the vertical section of the gate structure (such that the trench is formed under the channel). Of course, those of skill in the art will recognize that other configurations are also contemplated by the invention, depending on the specific gate structure design.

In FIG. 6, the trench 22 is filled with a stress material 24. In embodiments, the stress material is an oxide material which is preferably different than the BOX layer 12. This will provide the stress component to the device. In embodiments, the oxide material 24 is a spin on material or other types of oxides such as, for example, TEOS (Tetraethyl orthosilicate). In further implementations, a HARP (High Aspect Ratio Process) is contemplated where a thermal, non-plasma-based CVD (Chemical Vapor Deposition) solution is used with an ozone/TEOS chemistry to fill the trench 22. It should be understood that the stress material 24 also acts as an isolation material for an STI structure.

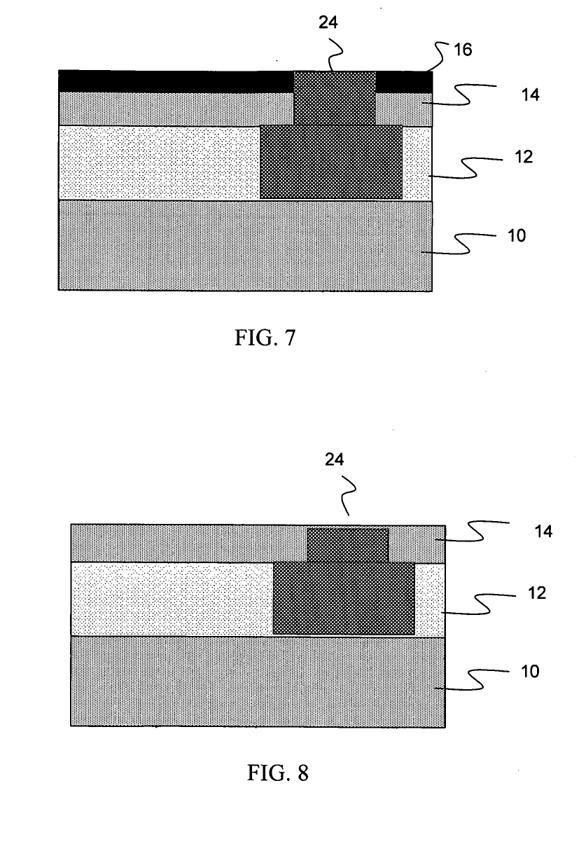

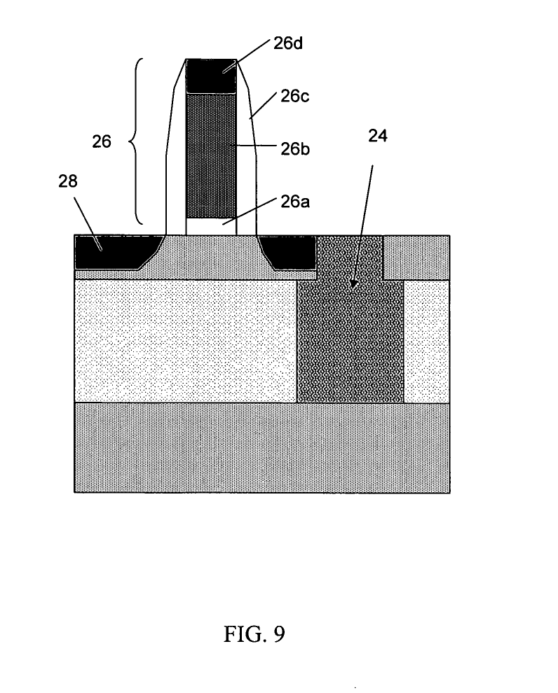

In FIG. 7, excess stress material 24 is planarized (stripped or removed) from a top of the structure of FIG. 6, using conventional processes. In FIG. 8, the pad nitride layer is also planarized exposing the SOI layer 14.

FIG. 9 shows conventional formation of a gate structure 26. For example, using conventional processes an oxide layer 26a and polysilicon gate 26b are deposited and patterned on the SIO layer. Sidewalls 26c such as, for example, nitride, oxide or nitride oxide are formed on sides of the oxide layer 26a and polysilicon gate 26b. A nitride cap 26d is formed the polysilicon gate 26b. Source and drain regions 28 are doped using conventional processes. Also, as shown in FIG. 9, the stress material 24 extends under the source and/or drain region 28 (within the BOX 12 ). This provides a stressful, laterally expanded STI structure which increases device performance, while providing the request isolation.

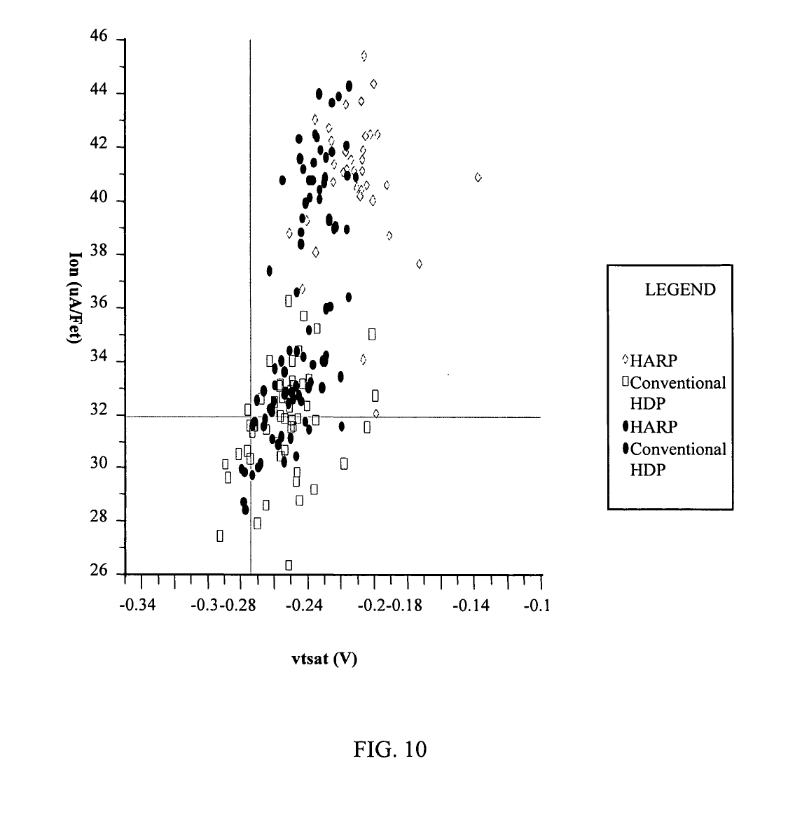

FIG. 10 is a graph showing improvements which are attainable in implementing the present invention. More specifically, using HARP the graph of FIG. 10 shows a 30% ion improvement with HARP STI for a narrow PFET device as compared to a conventional high density plasma (HDP) STI structure. That is, there is clearly an improvement in device performance due to the stress material in the STI structure. It is also noteworthy there is no discernable degradation to an NFET using, for example, HARP.

Moreover, Table 1 shows a strain enhancement improvement for an NFET and a PFET, implementing the processes and structure of the present invention. For example, Table 1 shows strain enhancement on (001) surface with the source/drain along <110> direction. More specifically, NFET improvement is shown to occur with the present invention by providing any or a combination of longitudinal tensile stress component and a transverse stress component, as well as a vertical compressive stress component. Also, PFET improvement is shown to occur with the present invention by providing any or a combination of longitudinal compressive stress component and a transverse tensile stress component, as well as a vertical tensile stress component. All are measured as x 1E-12 cm2/dyne and the relationship between mobility and stress is roughly calculated as:

TABLE 1
$\frac{Δ μ}{μ} \approx \vert {π}_{x} {σ}_{x} + {π}_{y} {σ}_{y} + {π}_{z} {σ}_{z} \vert$

| Direction | | Si Piezoresistive Coefficient, π | | |
|---|---|---|---|---|
| Current | Stress, σ | | NFET | PFET |
| X | X (longitudinal) | (π₁₁ + π₁₂ + π₄₄) | −31.6 | 71.8 |
| X | Y (transverse) | (π₁₁ + π₁₂ − π₄₄) | −17.6 | −66.3 |
| X | Z (vertical) | π₁₂ | 53.4 | −1.1 |

The resulting integrated circuit chips of each aspect of the invention can be distributed by the fabricator in raw wafer form (that is, as a single wafer that has multiple unpackaged chips), as a bare die, or in a packaged form. In the latter case, the chip is mounted in a single chip package (e.g., a plastic carrier, with leads that are affixed to a motherboard or other higher level carrier) or in a multichip package (e.g., a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

### Design Structure

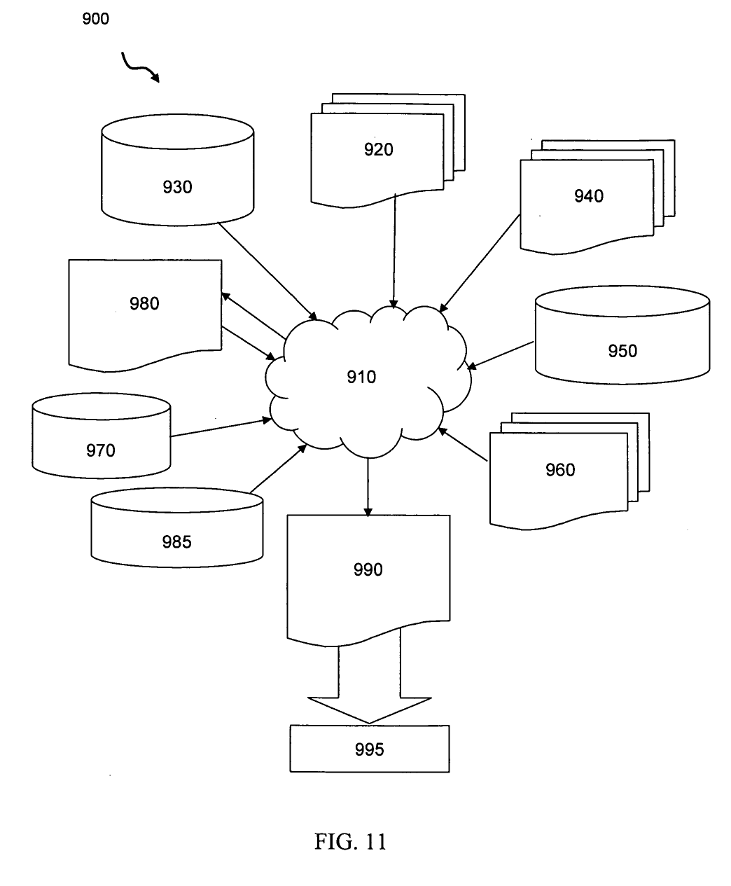

FIG. 11 shows a block diagram of an exemplary design flow 900 used for example, in semiconductor design, manufacturing, and/or test. Design flow 900 may vary depending on the type of IC being designed. For example, a design flow 900 for building an application specific IC (ASIC) may differ from a design flow 900 for designing a standard component. Design structure 920 is preferably an input to a design process 910 and may come from an IP provider, a core developer, or other design company or may be generated by the operator of the design flow, or from other sources. Design structure 920 comprises an embodiment of the invention as shown in FIG. 9 in the form of schematics or HDL, a hardware-description language (e.g., Verilog, VHDL, C, etc.).

Design structure 920 may be contained on one or more machine-readable medium. For example, design structure 920 may be a text file or a graphical representation of an embodiment of the invention as shown in FIG. 9. Design process 910 preferably synthesizes (or translates) an embodiment of the invention as shown in FIG. 9 into a netlist 980, where netlist 980 is, for example, a list of wires, transistors, logic gates, control circuits, I/O, models, etc. that describes the connections to other elements and circuits in an integrated circuit design and recorded on at least one of machine readable medium. This may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations, for a given manufacturing technology (e.g., different technology nodes, 32 nm, 45 nm, 90 nm, etc.), design specifications 940, characterization data 950, verification data 960, design rules 970, and test data files 985 (which may include test patterns and other testing information).

Design process 910 may further include, for example, standard circuit design processes such as timing analysis, verification, design rule checking, place and route operations, etc. One of ordinary skill in the art of integrated circuit design can appreciate the extent of possible electronic design automation tools and applications used in design process 910 without deviating from the scope and spirit of the invention. The design structure of the invention is not limited to any specific design flow.

Design process 910 preferably translates an embodiment of the invention as shown in FIG. 9, along with any additional integrated circuit design or data (if applicable), into a second design structure 990. Design structure 990 resides on a storage medium in a data format used for the exchange of layout data of integrated circuits (e.g. information stored in a GDSII (GDS2), GL1, OASIS, or any other suitable format for storing such design structures). Design structure 990 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 9. Design structure 990 may then proceed to a stage 995 where, for example, design structure 990: proceeds to tape-out, is released to manufacturing, is released to a mask house, is sent to another design house, is sent back to the customer, etc.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements, if any, in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A method comprising:
forming an isolation trench through a SOI layer and an underlying BOX layer; and
filling the isolation trench with stress material having characteristics different than the BOX layer.

2. The method of claim 1, wherein the forming is provided by an etching process.

3. The method of claim 2, wherein the etching process is an isotropic etching process in the BOX layer which forms the isolation trench under the SOI layer.

4. The method of claim 1, wherein the stress material is an oxide based material.

5. The method of claim 4, wherein the oxide based material is TEOS.

6. The method of claim 4, wherein the oxide based material is ozone TEOS.

7. The method of claim 4, wherein the oxide based material is deposited by a spin on method.

8. The method of claim 1, wherein the isolation trench extends under a source and/or drain region of a gate structure.

9. The method of claim 1, wherein the isolation trench and oxide based material form a isolation structure within the BOX.

10. The method of claim 1, wherein the isolation trench extends under a channel region of a gate structure.

11. The method of claim 1, wherein
the forming the isolation trench comprises:
forming an opening in a nitride layer which is deposited over the SOI layer;
forming an opening in the SOI layer; and
forming a trench in the BOX layer to an underlying substrate using an isotropic etching process in order to from a portion of the trench under the SOI layer and extend toward a channel region of a gate structure; and
the filling the isolation trench with stress material comprises:
filing the isolation trench with the oxide based material;
removing excess oxide based material from a top surface; and
removing the nitride layer; and
further comprising forming a gate structure adjacent to the filled isolation trench.

12. A structure comprising a trench isolation structure formed in a BOX layer and extending toward an underlying substrate and underneath an overlying SOI layer, the trench isolation structure being filled with an oxide based material that has characteristics different from the BOX layer and which provides a stress component to an adjacent gate structure.

13. The structure of claim 12, wherein the oxide based material is a spin on material.

14. The structure of claim 12, wherein the oxide based material is TEOS.

15. The structure of claim 12, wherein the oxide based material is ozone TEOS.

16. The structure of claim 12, wherein the trench isolation structure is at least beneath a source and/or drain region of the gate structure, extending toward a channel.

17. The structure of claim 12, wherein the trench isolation structure provides at least one of a longitudinal tensile stress component, a transverse stress component and a vertical compressive stress component for an NFET and a longitudinal compressive stress component, a transverse tensile stress component and a vertical tensile stress component for a PFET.

18. The structure of claim 12, wherein the trench isolation structure extends to the underlying substrate.

19. A design structure embodied in a machine readable medium for designing, manufacturing, or testing an integrated circuit, the design structure comprising a trench isolation structure formed in a BOX layer and extending toward an underlying substrate and underneath an overlying SOI layer, the trench isolation structure being filled with an oxide based material that has characteristics different from the BOX layer and which provides a stress component to an adjacent gate structure.

20. The design structure of claim 19, wherein one of:
the design structure comprises a netlist;
the design structure resides on storage medium as a data format used for the exchange of layout data of integrated circuits; and
the design structure resides in a programmable gate array.
